(19) United States
(12) Patent Application Publication
(10) Pub. No.: US 2025/0218828 A1
(43) Pub. Date: Jul. 3, 2025

(54) CONCURRENT SEMICONDUCTOR PROCESSING AND INSPECTION

(71) Applicant: DR Laser Singapore Pte Ltd., Singapore (SG)

(72) Inventors: Chi Hang KWOK, Singapore (SG); Kit Ying CHAN, Singapore (SG)

(73) Assignee: DR Laser Singapore Pte Ltd., Singapore (SG)

(21) Appl. No.: 18/991,842

(22) Filed: Dec. 23, 2024

(30) Foreign Application Priority Data
Dec. 28, 2023 (CN) 202323617261.1

(51) Int. Cl. H01L 21/67; H01L 21/66

(52) U.S. Cl. CPC H01L 21/67259; H01L 22/12

(57) ABSTRACT

Systems and methods for concurrent processing and inspection of semiconductor devices are provided. Disclosed systems include multi-layered holders for supporting processes semiconductor devices and materials, which are hollow and configured in a way that enables coaxially aligning the processing head and the inspection head and positioning and maintaining the semiconductor device and materials at a plane perpendicular to the alignment axis during processing and inspection thereof. Disclosed configurations provide real-time feedback to ensure positional accuracy of the processing head, the semiconductor device and materials during the processing thereof. The multi-layer and multi-functional platform for semiconductor processing provides a system designed to work in synergy to facilitate precise semiconductor processing, real-time inspection, and alignment.

### CROSS REFERENCE TO RELATED APPLICATIONS

This application claims priority from Chinese Patent Application No. 202323617261.1, filed on Dec. 28, 2023, which is incorporated herein by reference in its entirety.

### BACKGROUND OF THE INVENTION

### 1. Technical Field

The present invention relates to the field of semiconductor processing and inspection, and more particularly, to a multi-layer platform that facilitates advanced and concurrent processing and inspection of semiconductors.

### 2. Discussion of Related Art

Prior to setting forth the background of the related art, it may be helpful to set forth definitions of certain terms that will be used hereinafter.

### SUMMARY OF THE INVENTION

The following is a simplified summary providing an initial understanding of the invention. The summary does not necessarily identify key elements nor limit the scope of the invention, but merely serves as an introduction to the following description.

One aspect of the present invention provides a system for concurrent processing and inspection of semiconductor devices, the system comprising: a holder configured to support a semiconductor device and semiconductor materials to be deposited onto the semiconductor device during processing thereof, wherein the holder comprises a plurality of layers, and is movable in multiple directions, a processing head configured to process the semiconductor device, and an inspection head configured to inspect in real-time the processing of the semiconductor device, wherein: the processing head and the inspection head are coaxially aligned and the holder is configured to position the semiconductor device and the semiconductor materials at a plane perpendicular to the alignment axis, and maintain the semiconductor device and the semiconductor materials parallel to the plane during processing and inspection thereof, and the inspection head is configured to provide real-time feedback to ensure positional accuracy of the processing head, the semiconductor device and the semiconductor materials during the processing thereof

One aspect of the present invention provides a method of concurrent processing and inspection of semiconductor devices using the disclosed systems, the method comprising: clamping the semiconductor device onto the holder, coaxially aligning the plurality of layers of the holder, and using at least one hollow frame of the holder to align the layers of the holder through independent or synchronized movements.

One aspect of the present invention provides a method of concurrent processing and inspection of semiconductor devices, the method comprising: configuring a holder to support a semiconductor device and semiconductor materials to be deposited onto the semiconductor device during processing thereof, wherein the holder comprises a plurality of layers, and is movable in multiple directions, configuring a processing head to process the semiconductor device using the semiconductor materials, configuring the inspection head to inspect in real-time the processing of the semiconductor device, coaxially aligning the processing head and the inspection head, configuring the holder to position the semiconductor device and the semiconductor materials at a plane perpendicular to the alignment axis, maintaining the semiconductor device and the semiconductor materials parallel to the plane during processing and inspection thereof, and configuring the inspection head to provide real-time feedback to ensure positional accuracy of the processing head, the semiconductor device and the semiconductor materials during the processing thereof.

One aspect of the present invention provides a computer program product comprising a non-transitory computer readable storage medium having computer readable program embodied therewith, the computer readable program comprising: computer readable program configured to control concurrent processing and inspection of semiconductor devices by coaxially aligning a processing head configured to process a semiconductor device and an inspection head configured to inspect in real-time the processing of the semiconductor device, and computer readable program configured to control a holder, configured to support the semiconductor device and semiconductor materials to be deposited onto the semiconductor device during processing thereof, the holder comprising a plurality of layers, and being movable in multiple directions—to position the semiconductor device at a plane perpendicular to the alignment axis, and maintain the semiconductor device and the semiconductor materials parallel to the plane during processing and inspection thereof.

These, additional, and/or other aspects and/or advantages of the present invention are set forth in the detailed description which follows, possibly inferable from the detailed description, and/or learnable by practice of the present invention.

### BRIEF DESCRIPTION OF THE DRAWINGS

For a better understanding of embodiments of the invention and to show how the same may be carried into effect, reference will now be made, purely by way of example, to the accompanying drawings in which like numerals designate corresponding elements or sections throughout. In the accompanying drawings:

FIG. 1 is a high-level schematic illustration of a system for concurrent processing and inspection of semiconductor devices, according to some embodiments of the invention.

FIGS. 2 and 3 are high-level schematic illustrations of layers of the holder, according to some embodiments of the invention.

FIGS. 4A and 4B are high-level schematic illustrations of layers of holders with the semiconductor materials and device, according to some embodiments of the invention.

FIGS. 5A-5C are high-level schematic illustrations of processing and inspection systems, according to some embodiments of the invention.

FIGS. 6A and 6B are high-level schematic illustrations of operation stages of disclosed systems, according to some embodiments of the invention.

FIGS. 7A-7C are high-level schematic illustrations of compensation and adjustments of the holder layers to achieve parallelism, according to some embodiments of the invention.

FIGS. 8 and 9 are high-level schematic illustrations of potential motions and adjustments operable by the holder layers, according to some embodiments of the invention.

FIG. 10 is a high-level schematic illustration of the real-time alignment and inspection during material processing within the multi-layer and multi-functional system, according to some embodiments of the invention.

FIG. 11 is a high-level flowchart illustrating methods of semiconductor processing using a multi-layer platform, according to some embodiments of the invention.

FIG. 12 is a high-level block diagram of exemplary controllers, which may be used with embodiments of the present invention.

FIG. 13 is a high-level flowchart illustrating methods of concurrent processing and inspection of semiconductor devices, according to some embodiments of the invention.

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

### DETAILED DESCRIPTION OF THE INVENTION

In the following description, various aspects of the present invention are described. For purposes of explanation, specific configurations and details are set forth in order to provide a thorough understanding of the present invention. However, it will also be apparent to one skilled in the art that the present invention may be practiced without the specific details presented herein. Furthermore, well-known features may have been omitted or simplified in order not to obscure the present invention. With specific reference to the drawings, it is stressed that the particulars shown are by way of example and for purposes of illustrative discussion of the present invention only, and are presented in the cause of providing what is believed to be the most useful and readily understood description of the principles and conceptual aspects of the invention. In this regard, no attempt is made to show structural details of the invention in more detail than is necessary for a fundamental understanding of the invention, the description taken with the drawings making apparent to those skilled in the art how the several forms of the invention may be embodied in practice.

Before at least one embodiment of the invention is explained in detail, it is to be understood that the invention is not limited in its application to the details of construction and the arrangement of the components set forth in the following description or illustrated in the drawings. The invention is applicable to other embodiments that may be practiced or carried out in various ways as well as to combinations of the disclosed embodiments. Also, it is to be understood that the phraseology and terminology employed herein are for the purpose of description and should not be regarded as limiting.

Unless specifically stated otherwise, as apparent from the following discussions, it is appreciated that throughout the specification discussions utilizing terms such as “processing”, “computing”, “calculating”, “determining”, “enhancing”, “deriving” or the like, refer to the action and/or processes of a computer or computing system, or similar electronic computing device, that manipulates and/or transforms data represented as physical, such as electronic, quantities within the computing system's registers and/or memories into other data similarly represented as physical quantities within the computing system's memories, registers or other such information storage, transmission or display devices.

Some embodiments of the present invention provide efficient and economical methods and mechanisms for concurrent processing and inspection of semiconductor devices and thereby provide improvements to the technological field of semiconductor device processing.

Systems and methods for concurrent processing and inspection of semiconductor devices are provided. Disclosed systems include multi-layered holders for supporting processes semiconductor devices and materials, which are hollow and configured in a way that enables coaxially aligning the processing head and the inspection head and positioning and maintaining the semiconductor device and materials at a plane perpendicular to the alignment axis during processing and inspection thereof. Disclosed configurations provide real-time feedback to ensure positional accuracy of the processing head, the semiconductor device and materials during the processing thereof. The multi-layer and multi-functional platform for semiconductor processing provides a system designed to work in synergy to facilitate precise semiconductor processing, real-time inspection, and alignment.

Disclosed embodiments solve challenges that face prior art technologies, such as: (i) Integration challenges: The discrete nature of processing and inspection prior art platforms poses significant hurdles in achieving seamless integration and synchronization. This segregation often results in prolonged processing durations and potential mishandling risks during semiconductor transfers; (ii) Spatial inefficiencies: The need for separate prior art platforms for each function require substantial space, leading to higher infrastructure costs and reduced scalability opportunities; (iii) Precision concerns: The inherent static design of many prior art platforms, combined with reliance on external alignment tools, introduced chances of misalignment, especially during high-volume operations. Such minute misalignments could culminate in significant quality challenges in the end semiconductor products; (iv) Operational delays: The need to manually transfer semiconductors between prior art platforms, combined with manual interventions for alignments and checks, contributed to operational delays a critical concern in a high-volume industry; (v) Troubleshooting complexities: Identifying defects during the inspection phase and subsequently tracing them back to the exact processing phase or determining the root cause was invariably complex. The absence of real-time feedback loops in prior art platforms often means that certain defects could remain undetected for prolonged periods, leading to considerable production setbacks.

Advantageously, disclosed systems and methods solve a pressing need for an evolved platform that could amalgamate multiple functions, ensure real-time alignments, and provide a streamlined pathway from processing to inspection. In various embodiments, disclosed platform systems and methods for semiconductor processing address the prevailing challenges in the field, with their unique multi-layer design, combined with features such as the coaxial hollow structure and multidirectional movement capabilities, positions it as an advanced solution for semiconductor manufacturers aiming for precision, flexibility, and efficiency.

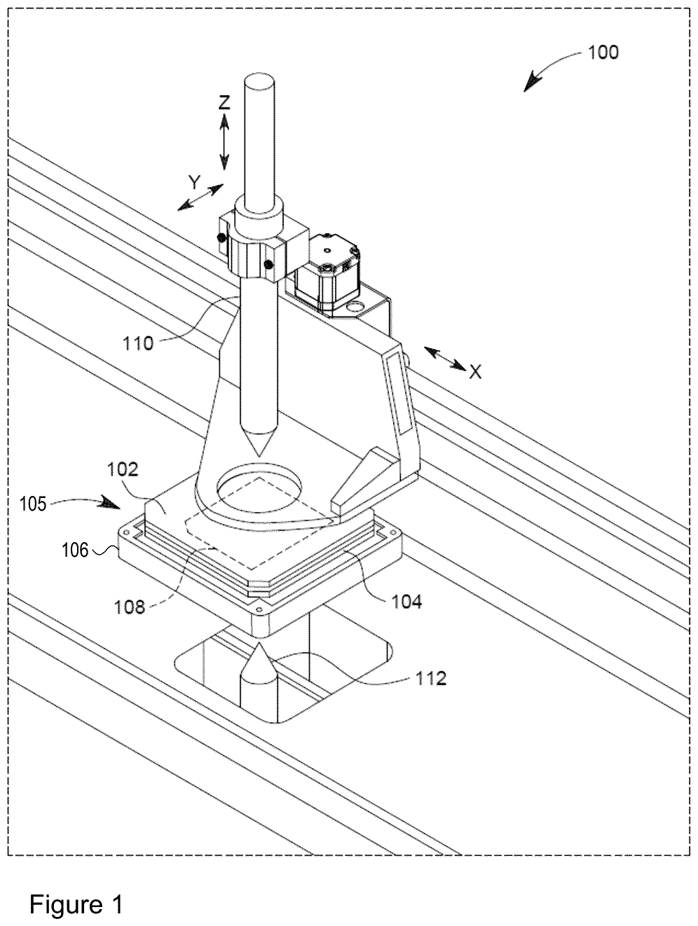

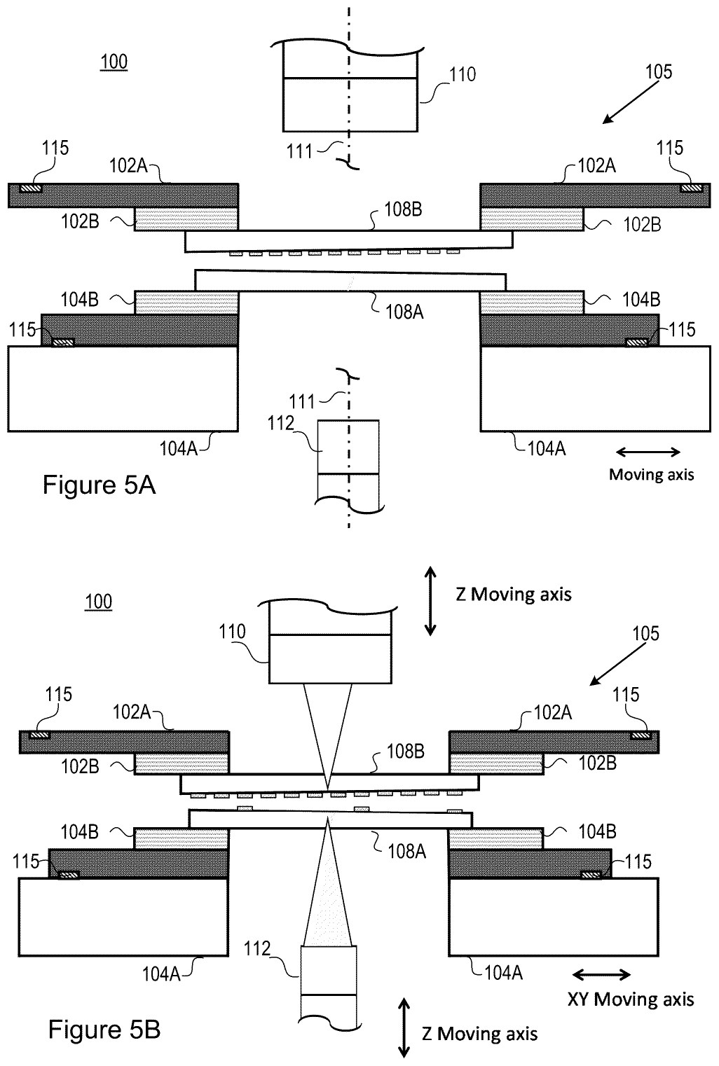

FIG. 1 is a high-level schematic illustration of a system 100 for concurrent processing and inspection of semiconductor devices 108, according to some embodiments of the invention. System 100 comprises a holder 105 configured to support semiconductor device and semiconductor materials to be deposited onto the semiconductor device during processing thereof (denoted collectively 108, and see FIG. 4A). Holder 105 comprises a plurality of layers (e.g., layers 102, 104), and is movable in multiple directions. System 100 further comprises a processing head 110 configured to process semiconductor device 108, and an inspection head 112 configured to inspect in real-time the processing of semiconductor device 108 (illustrated schematically by its location in FIG. 1). For example, the semiconductor device may be processed by applying materials and/or components from the semiconductor materials indicated schematically.

Processing head 110 and inspection head 112 are coaxially aligned and holder 105 is configured to position semiconductor device and the semiconductor materials 108 at a plane perpendicular to the alignment axis 111, and maintain semiconductor device 108 parallel to the plane during processing and inspection thereof. For example, in a non-limiting example, alignment axis 111 of processing head 110 and inspection head 112 is illustrated in FIG. 1 along the z axis, while the plane to which semiconductor device 108 is parallel is indicated in FIG. 1 by the x and y axes, which define the plane perpendicular to alignment axis 111.

Inspection head 112 is configured to provide real-time feedback to ensure positional accuracy of processing head 110 and semiconductor device 108 during the processing thereof. It is noted that the layers of holder 105 may be arranged to maintain the positional accuracy of semiconductor device 108 (and optionally the semiconductor materials) with respect to the defined plane perpendicular to the alignment axis of processing head 110 and inspection head 112.

System 100 may comprise a multi-layer and multi-functional platform for semiconductor processing, which has a plurality of mechanical layers designed to work in synergy to facilitate precise semiconductor processing, real-time inspection, and alignment. The mechanical layers include, in a schematic non-limiting example, a first layer comprising processing head 110, a multidirectional moving holder 105 comprising a plurality of layers (e.g., second layer 102 and third layer 104, e.g., clamping semiconductor device 108 that is being processed and inspected, as disclosed herein), and a fourth layer comprising inspection head 112. It is noted that the term mechanical layer as applied to processing head 110 and inspection head 112 refers generally to these components being part of a mechanical structure (as the central part of system 100) with tightly controlled spatial relations, as disclosed herein.

For example, the first layer comprising processing head 110 houses various components essential for material processing. Components may include, but are not limited to, one or more laser head(s), one or more scan lens(es), one or more objective lens(es), one or more mechanical pick and place working part(s), one or more needle(s), one or more sensor(s), one or more detector(s), and one or more camera(s). The first layer comprising processing head 110 is, in some embodiments, instrumental in performing the actual processing tasks on semiconductor materials of semiconductor device 108.

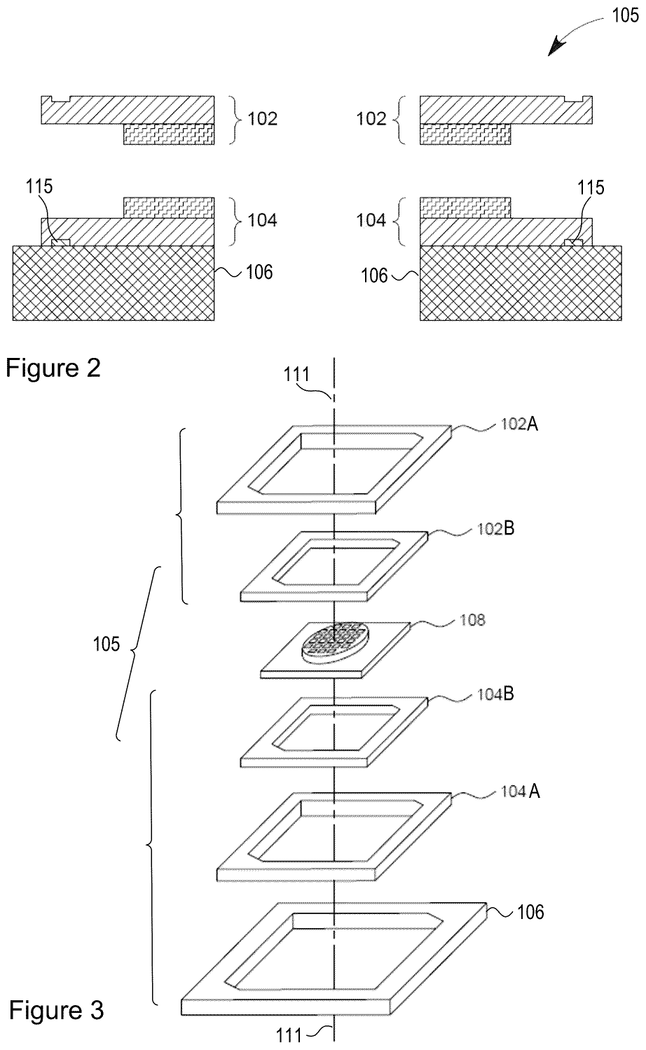

Holder 105 comprises a plurality of multi-directionally moving layers, e.g., each configured to perform its function independently as disclosed herein. The layers of holder 105 securely hold and position the semiconductor device and materials for processing, and are designed to move multi-directionally, allowing precise alignment and positioning of the materials to fabricate semiconductor device 108 (see FIGS. 2, 3, 8 and 10 for non-limiting examples for the holder layers, and FIGS. 4-7, 9 and 10 for non-limiting examples for their alignment and function).

For example, the fourth layer comprising inspection head 112 comprises a sensing mechanism equipped with multiple components like lighting, cameras, thermal sensors, and detectors. Inspection head 112, designated schematically in a non-limiting manner as the fourth layer, is designed for real-time inspection and feedback on the position accuracy of the layers of holder 105 and semiconductor device 108 supported by holder 105—relative to processing head 110, ensuring precise processing and alignment.

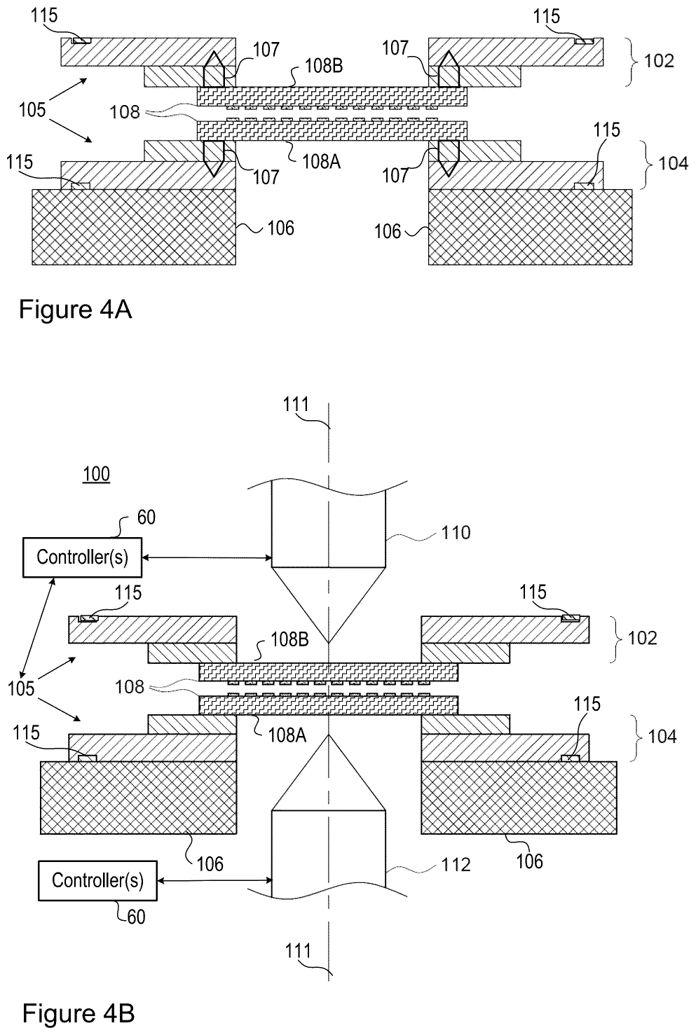

It is noted that the schematic numbering of the mechanical layers (as first, second, third and fourth) is in no way limiting, as, e.g., holder 105 may comprise more than two layers, illustrated schematically, e.g., in FIGS. 2 and 3. In other words, at least the second and the third mechanical layers may each comprise one, two or more layers, which may be operated as disclosed herein.

FIGS. 2 and 3 are high-level schematic illustrations of layers of holder 105, according to some embodiments of the invention. FIG. 2 is a schematic cross section view of holder 105, and FIG. 3 is a schematic exploded view of the layers of holder 105 and semiconductor device 108 and semiconductor materials to be applied onto semiconductor device 108 (indicated in a highly schematic manner).

Holder 105 may comprise at least one hollow frame 106 configured to support semiconductor device 108 and allow optical access of processing head 110 and inspection head 112 to semiconductor device 108. Hollow frame 106 may comprise, or support multiple mechanical layers 102, 104 that are coaxially aligned, with frame 106 as a hollow coaxial feature across the holder layers, configured to allow alignment of the mechanical layers by independent or synchronized movement. Hollow frame 106 with mechanical layers 102, 104 may be further configured to enable real-time alignment and feedback of position accuracy during processing, eliminating possible lateral offset between the inspection axis and the processing axis (both along the z axis).

For example, holder 105 may comprise top layer 102 comprising an upper clamping surface 102B and bottom layer 104 comprising a lower clamping surface 104B configured to support semiconductor device 108. Upper clamping surface 102B and lower clamping surface 104B may be supported by respective upper frame 102A and lower frame 104A, illustrated schematically, which may be tilted as required to align semiconductor device 108 at the x-y plane, perpendicular to the alignment (z) axis. Adjustment of the tile of any of the layers of holder 105 may be adjusted using various types of compensations mechanisms, e.g., employing actuators 115, illustrated schematically, e.g., in FIGS. 2, 4-8 and 10.

In various embodiments, the layers of holder 105 may be arranged to be movable in multiple directions—to hold and precisely position semiconductor device 108 and optionally the semiconductor materials for processing. Top and bottom layers 102, 104, respectively, may be configured to secure holding surface for semiconductor device 108, ensuring semiconductor device 108 and materials remain in the precise position during the processing phase. The operational interaction between top and bottom layers 102, 104, respectively, enables the accurate processing of semiconductor materials. Top and bottom layers 102, 104, respectively, may move in synchronization or independently along multiple axes, enabling precise alignment and positioning of the materials. The movement of top and bottom layers 102, 104, respectively, may be configured to allow a range of motions, e.g., along the x, y, and z axes, and potentially a 360-degree movement ensuring semiconductor device 108 and the materials are precisely positioned for processing semiconductor materials onto semiconductor device 108. Clamping surfaces 102B, 104B may be made, in non-limiting examples, of ceramic, metallic and/or electrostatic materials, e.g., equipped with suction or vacuum mechanism(s) to securely hold the processing materials and semiconductor device 108.

FIG. 3 illustrates schematically frames and layers of holder 105, which are coaxial and hollow to support semiconductor device and semiconductor materials 108 and enable processing and inspection thereof by multi-layer and multi-functional system 100. Holder 105 with disclosed frame(s) and layer(s) plays a pivotal role in facilitating real-time alignment and inspection during the processing phase. The coaxial alignment of multi-layer system 100 ensures precise positioning and parallelism necessary for accurate semiconductor processing. Besides facilitating alignment, the coaxial hollow structure of holder 105 also enables real-time feedback on the position accuracy of the layers of holder 105 and of semiconductor device 108 relative to processing head 110 and relative to inspection head 112. The real time feedback ensuring that any misalignments are promptly detected and corrected, thereby enhancing the precision of the semiconductor processing.

Advantageously, compared to traditional designs that often have an offset between the inspection axis and the processing axis (which can introduce system errors), the disclosed coaxial hollow structure of holder 105 eliminates this offset, ensuring that the inspection and processing of the semiconductor materials and device 108 occur along the same axis 111. By allowing for real-time alignment and feedback, the coaxial hollow structure of holder 105 significantly enhances the precision and efficiency of the semiconductor processing system 100.

FIGS. 4A and 4B are high-level schematic illustrations of layers of holder 105 with semiconductor materials and device 108, according to some embodiments of the invention. FIG. 4A is a schematic cross section view of holder 105 and semiconductor materials and device 108, and FIG. 4B is a schematic cross section view of holder 105 with semiconductor materials and device 108 within processing and inspection system 100.

It is noted that semiconductor device 108 and the semiconductor materials to be applied onto semiconductor device 108 are indicated in a highly schematic manner—e.g., semiconductor device 108 may be one part denoted 108A, e.g., the top or the bottom part indicated, and semiconductor materials may be another part denoted 108B, e.g., the bottom or top part indicated, respectively. In various embodiments, processing head 110 may be set above semiconductor materials 108B and be configured to release materials and components therefrom onto semiconductor device 108A.

Non-limiting examples for semiconductor devices include various integrated circuits, typically produced on a substrate and including various components (e.g., various types of transistors, diodes, photocells, etc., and conducting traces, which are applied upon the substrate as the semiconductor materials disclosed herein. The semiconductor materials may comprise various types of materials (e.g., to fabricate traces) and components (e.g., for transfer onto the substrate). Non-limiting examples for semiconductor materials include glass-based wafers, sapphire-based wafers, silicon carbide wafers, silicon wafers, PCBs etc., with printed circuits by copper or gold wires, printed solder paste or other materials. Semiconductor materials may comprise various electronic components and integrated circuits (e.g., LEDs). Semiconductor materials may include transient materials, such as various photo-decomposable polymers and adhesives. It is noted that the distinction applied herein between semiconductor devices and semiconductor materials is functional, in the sense that semiconductor materials are used throughout the use of processing and inspection system 100 to deposit, process and transfer elements from the semiconductor materials to form the semiconductor devices according to specified instructions. Hence, any type of semiconductor materials used to fabricate semiconductor devices may be referred to as semiconductor materials 108B before fabrication, and part of semiconductor device 108A after fabrication.

As illustrated, processed materials and device 108 are securely placed and positioned between the second and third layers 102, 104, respectively, of holder 105 in system 100—comprising upper clamping surface 102 and lower clamping surface 104 of the multidirectional moving holder 105—illustrated in a highly schematical manner. The processing material may be securely clamped over upper and lower clamping surfaces 102B, 104B respectively (see FIG. 3), e.g., through continuous and constant suction or vacuum pressure exerted by suction or vacuum mechanism (indicated schematically by arrows 107).

In some embodiments, upper clamping surface 102B and lower clamping surface 104B may comprise chucks configured to support and hold respective semiconductor device 108A and semiconductor materials 108B, e.g., by applying continuous and constant suction or vacuum pressure exerted by suction or vacuum mechanism (indicated schematically by arrows 107). In various embodiments, chucks 102B, 104B may be made of various materials (e.g., ceramic, metallic, electrostatic or other types of materials) that can provide the required suction or vacuum 107 for supporting and holding the wafers of semiconductor device and materials 108A, 108B. Upper frame 102A and lower frame 104A may comprise XYθ stages (movable in x, y and θ directions, the latter denoting a range of tilting angles) with compensation mechanisms illustrated schematically by actuators 115.

FIG. 4B illustrates schematically the arrangement and interaction of processing head 110 (as a first layer) and inspection head 112 (as a fourth layer) with the plurality of holder layers 102, 104 and semiconductor materials and device 108.

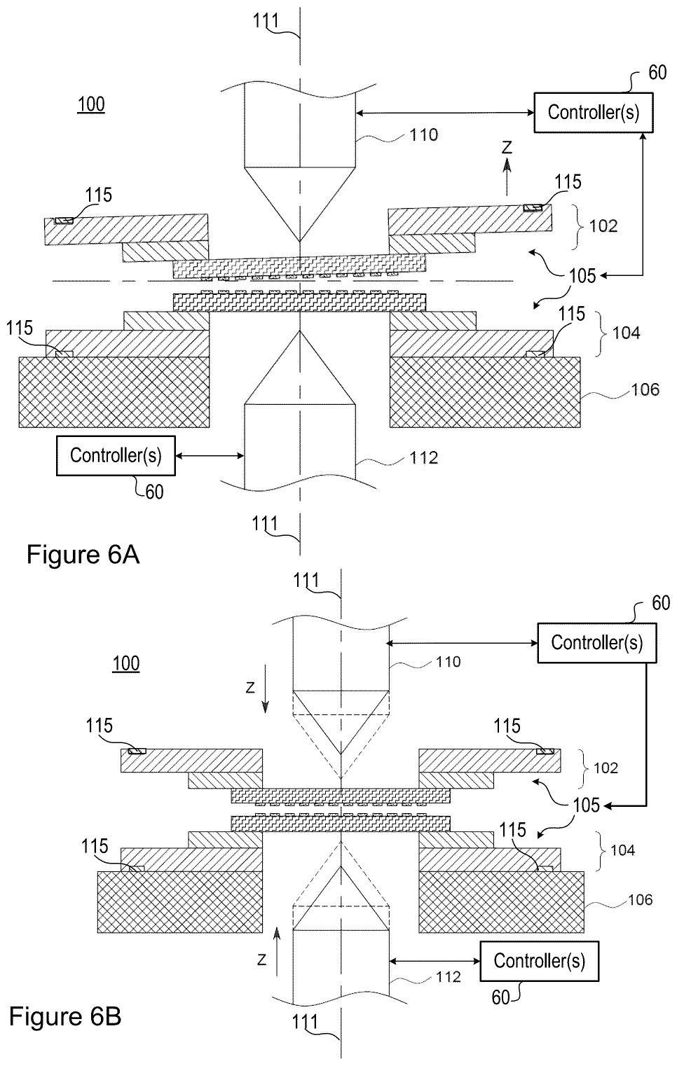

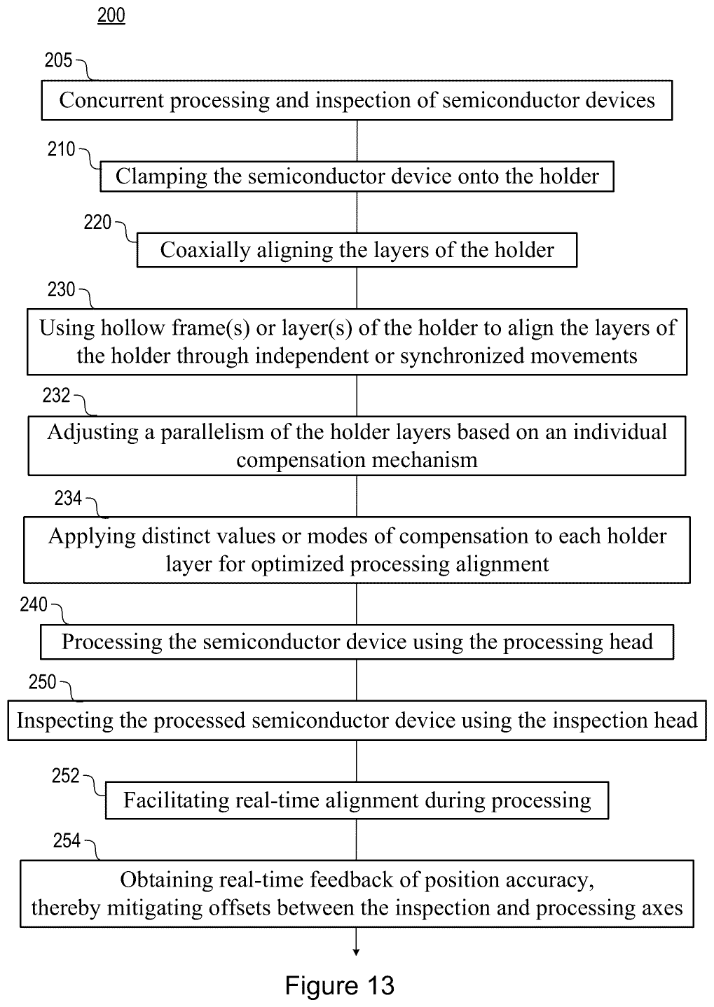

In various embodiments, system 100 may further comprise one or more controller(s) 60 configured to control holder 105, processing head 110 and inspection head 112 to maintain a coplanarity of the holder layers and semiconductor device 108, and their perpendicular relation to alignment axis 111 of processing head 110 and inspection head 112 during processing and inspection. For example, controller(s) 60 may be configured to implement a compensation mechanism 115 for adjusting orientations of the holder layers individually, as illustrated e.g., in FIGS. 6A and 6B. Controller(s) 60 are indicated schematically in a non-limiting manner in FIGS. 4B, 6A and 6B, and may include subunits as illustrated schematically in FIG. 12.

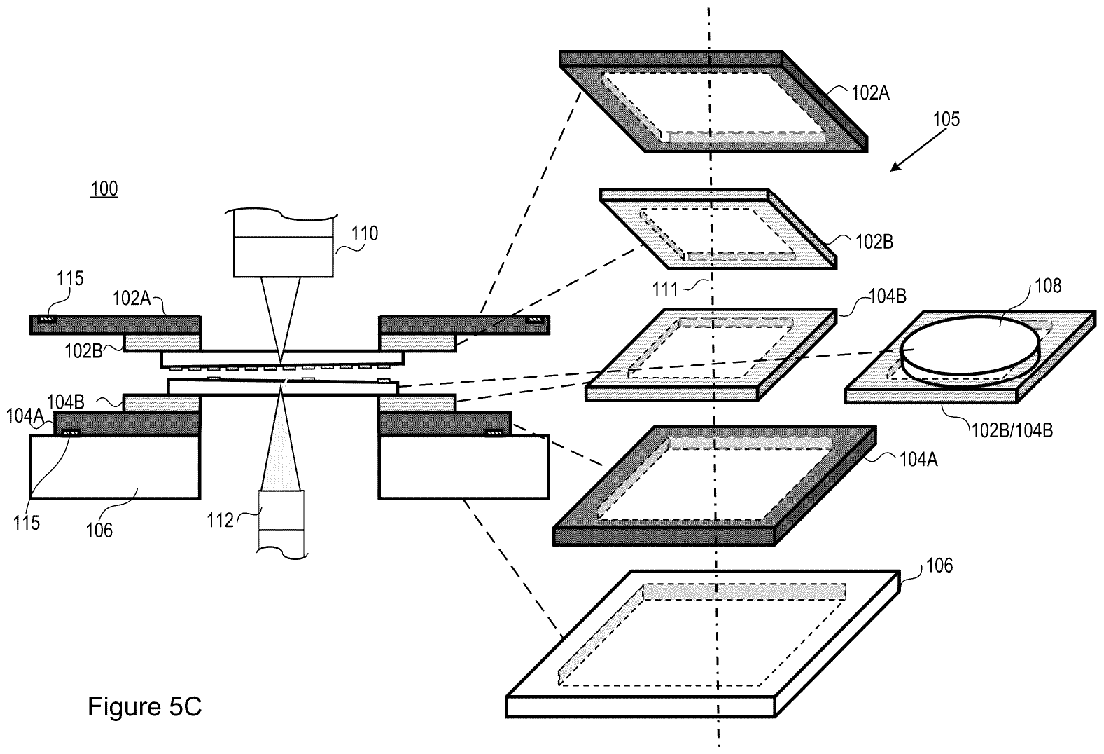

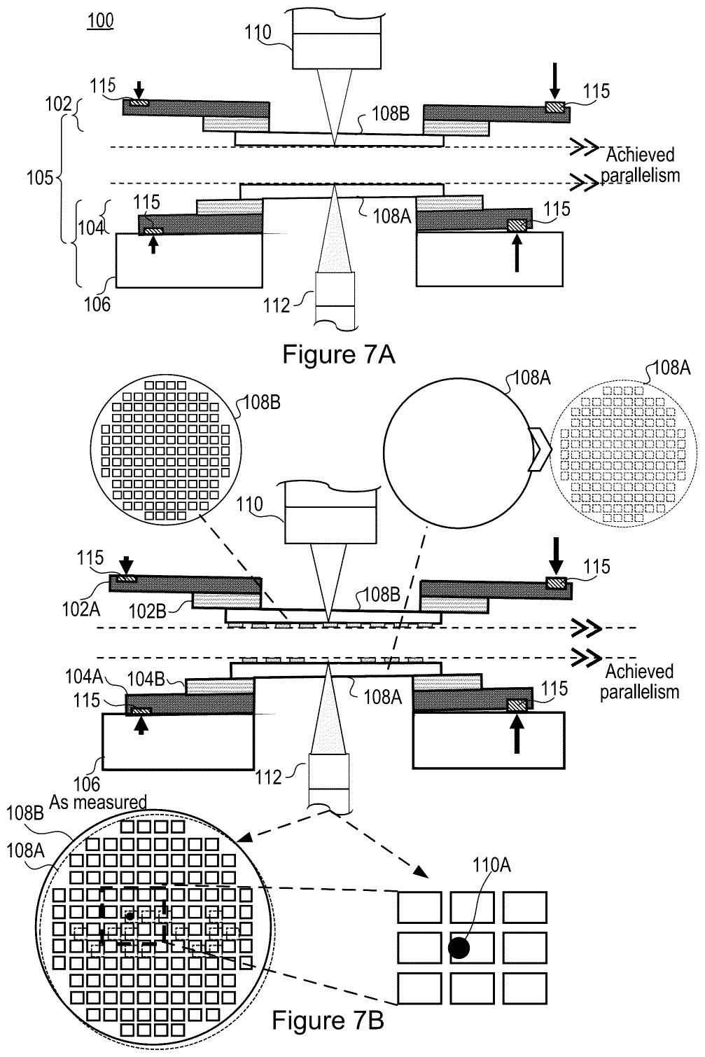

FIGS. 5A-5C are high-level schematic illustrations of processing and inspection system 100, according to some embodiments of the invention. FIGS. 5A and 5B illustrate schematically holder 105 with semiconductor materials 108B to be processed and during processing (respectively) onto device layer 108A. It is noted that in FIG. 5A and 5B, semiconductor materials 108B and device layer 108A are not completely parallel to each other, but are inclined at a slight angle that introduces errors, that are avoided according to embodiments of the present invention by applying corrections to make semiconductor materials 108B and device layer 108A exactly parallel, using compensation mechanisms such as actuators 115 described herein. It is emphasized that in operation, top and bottom layers 102, 104 are made parallel, as illustrated schematically e.g., in FIGS. 7A-7C.

FIG. 5A and 5B further illustrate schematically the movement directions of holder 105 and of processing head 110 and inspection head 112. It is further noted that FIG. 5B illustrates schematically a processing stage in which some elements from semiconductor materials layer 108B have already been processed and transferred to device layer 108A (compared to FIG. 5A). FIG. 5C provides a schematic high level exploded view of the layers of holder 105, according to some embodiments of the invention. Semiconductor materials 108B and device layer 108A are represented schematically as layer 108 that may be supported by top layer 102 and/or bottom layer 104 (e.g., by chucks 102B, 104B thereof, respectively), depending on the system configuration. It is noted that the hollow frames 102A, 102B, 104A, 104B may each have a rectangular, circular, ellipsoid or other shape, and are coaxial with respect to alignment axis 111, or at least provide sufficient central space to process semiconductor materials and device by co-axially aligned processing head 110 and inspection head 112. Semiconductor materials layer 108B and device layer 108A may each have a rectangular, circular, ellipsoid or other shape.

FIGS. 6A and 6B are high-level schematic illustrations of operation stages of system 100, according to some embodiments of the invention. FIGS. 6A and 6B are schematic cross section views of processing and inspection system 100 handling various scenarios of misalignment from the predefined working parallelism or coplanarity within the layer of system 100, which could potentially occur during processing of semiconductor devices 108.

FIG. 6A schematically illustrates a scenario in which one end of the second layer, namely top layer 102, e.g., upper clamping surface 102B-experiences a displacement in the Z-axis direction, which disturbs the predefined working parallelism or coplanarity of system 100. Similarly, such misalignment conditions may occur with respect to the third layer namely bottom layer 104 (e.g., lower clamping surface 104B), which disturbs the predefined working parallelism or coplanarity of the platform of the third layer.

FIG. 6B schematically illustrates a situation where both the first layer, namely processing head 110, and the fourth layer, namely inspection head 112-are misaligned in the Z-axis direction.

These and other misalignments may be caused by manufacturing tolerances, wear and tear, vibration and shock, improper installation or assembly, external forces, load changes, control system errors, calibration errors, etc.—and may be handled by disclosed multi-layer and multi-functional system 100 for semiconductor processing, as disclosed herein. Specifically, controller(s) 60 may detect any occurring misalignment and correct the respective misalignment by adjusting position(s) and/or tilting angle(s) of one or more of the layers in system 100, e.g., of any of processing head 110, inspection head 112 and/or one or more layers in holder 105, according to specified alignment rules—to coaxially re-align processing head 110, inspection head 112 and holder 105 and re-position the semiconductor device and the semiconductor materials 108 at a plane perpendicular to alignment axis 111.

FIGS. 7A-7C are high-level schematic illustrations of compensation and adjustments of the holder layers to achieve parallelism, according to some embodiments of the invention. The non-limiting examples demonstrate disclosed real time inspection and alignment compensation during wafer processing applied using the disclosed coaxial hollow structure design.

FIG. 7A illustrates schematically the adjustment of the inclinations of top and/or bottom layers 102, 104 respectively to achieve parallelism between semiconductor device and materials layers 108A, 108B-overcoming errors of various sources that may cause some tiling of either of the layers (as illustrated schematically in FIGS. 5A-5C). The compensations for the tilts are illustrated schematically by thick arrow indicating forces applied by actuators 115 on the respective layers, to compensate for the unwanted tilts. Clearly the compensations are adjusted to reverse the effects of unwanted inclinations, and achieve parallelism between semiconductor device and materials layers 108A, 108B.

FIG. 7B illustrates schematically the inspection results by inspection head 112, which are used to detect unwanted inclinations (deviations from parallelism) and further used to monitor the correction of the tilts by compensations applied through actuators 115 (e.g., supported by controllers 60 as disclosed herein). FIG. 7B schematically illustrates the fabrication of semiconductor device layers 108A using semiconductor materials layers 108B (on the top part of the figure) and the concurrent real-time inspection of the fabrication process by inspection head 112, indicating (on the bottom part of the figure) the deviation from parallelism by superposed images of semiconductor materials layers 108B and semiconductor device layers 108A, including an indication of the laser spot 110A used for fabrication by processing head 110 (e.g., to release semiconductor materials from layer 108B onto layer 108A, etch semiconductor materials deposited previously on layer 108A, etc.). Controller(s) 60 may be used to correct for detected errors by compensating for unwanted tilts by activating actuators 115, e.g., by applying a corresponding voltage to piezoelectric actuators 115 that yields a mechanical movement of the respective layers 102, 104 (e.g., 102A, 104A).

FIG. 7C illustrates schematically an even more extreme case of misalignment that can be handled by disclosed system 100, namely the inspection and alignment of semiconductor device and materials layers 108A, 108B even if the layers are apart with some offset in X and/or Y directions. The offset is illustrated schematically in the inspected image (on the right-hand side of the figure), and in spite of the offset, system 100 is able to detect unwanted tilting of layers 102 and/or 104 and correct the tilting by providing corresponding compensation through actuators 115 to restore parallelism of semiconductor device and materials layers 108A, 108B.

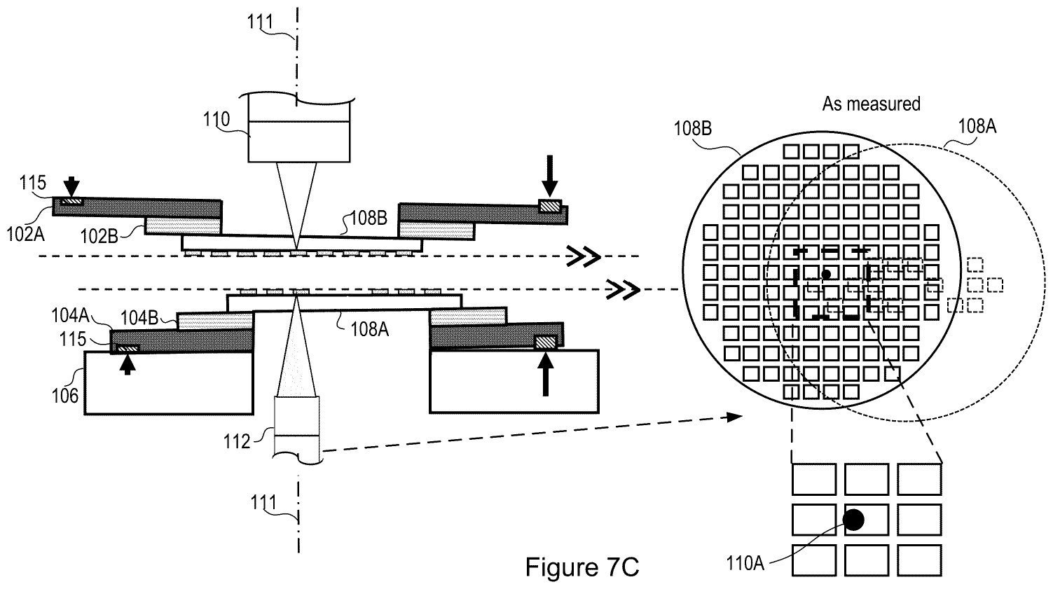

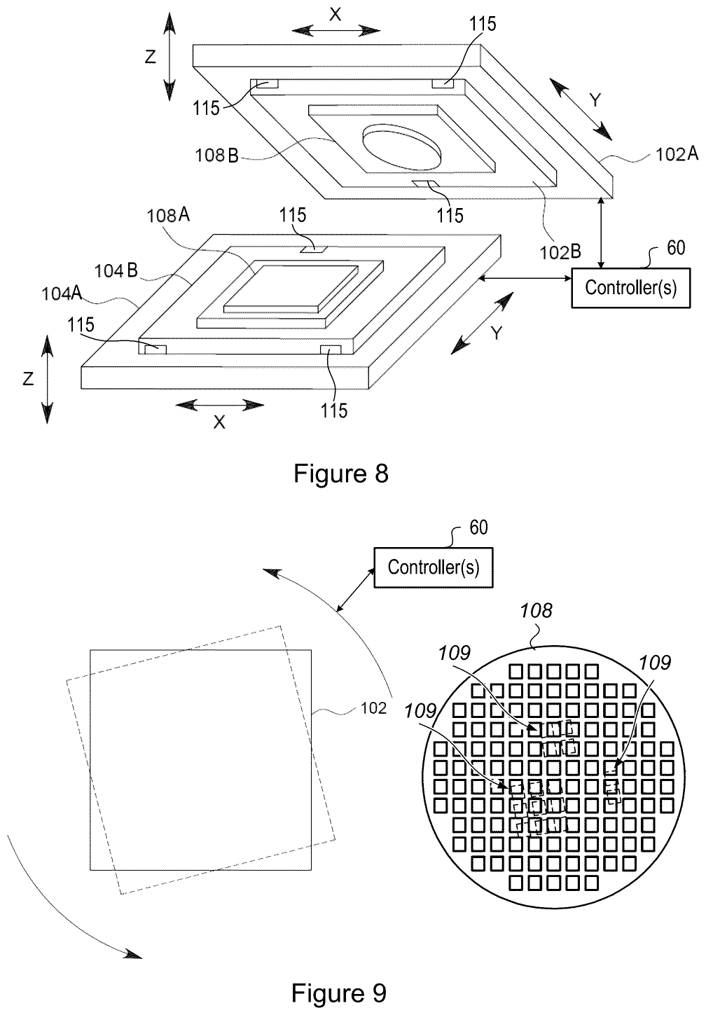

FIGS. 8 and 9 are high-level schematic illustrations of potential motions and adjustments operable by the holder layers, according to some embodiments of the invention. FIG. 8 is a schematic perspective illustration of some of the holder layers, supporting the semiconductor device and the semiconductor materials, FIG. 9 is a schematic illustration of rotational movements by top layer 102, as a non-limiting example, and their effect on depositing the semiconductor materials onto the semiconductor device

For example, FIG. 8 illustrates potential motions and adjustments of the second and third layers 102, 104, respectively, within multi-layer and multi-functional system 100 for semiconductor processing. FIG. 8 demonstrates schematically the range of motions that second and third layers 102, 104, respectively, can undertake along the X, Y, and Z axes (denotes schematically by the double-headed arrows). In addition to these possible movements, FIG. 9 demonstrates schematically the possibility to rotate or move top layer 102, as a non-limiting example, by up to a full circle (360°). These multidirectional movements are controlled by controller(s) 60, e.g., including individual compensation mechanism(s) 115, coupled with each layer and or sublayers (e.g., 102A, 102B, 104A, 104B, 106, etc.), for achieving precise alignment and positioning of semiconductor materials onto the semiconductor device. The movements along these axes are facilitated by the multidirectional moving holder 105 having multiple controllable layers, allowing for accurate alignment of semiconductor device 108A and semiconductor materials 108B with processing head 110 and inspection head 112. Schematic illustration of deposited semiconductor materials 109 onto semiconductor device 108 in FIG. 9 demonstrates schematically the high degree of flexibility and the precision control offered by system 100 in maneuvering the holder layers to cater to the processing requirements.

In various embodiments, the individual compensation mechanisms 115 implemented by controller(s) 60 to resolve and correct various types of in accuracies-allows for individual parallelism adjustments to the holder layers by adopting and applying respective values or modes of compensation to the holder layers independently to ensure precise alignment and parallelism essential for high-precision semiconductor processing.

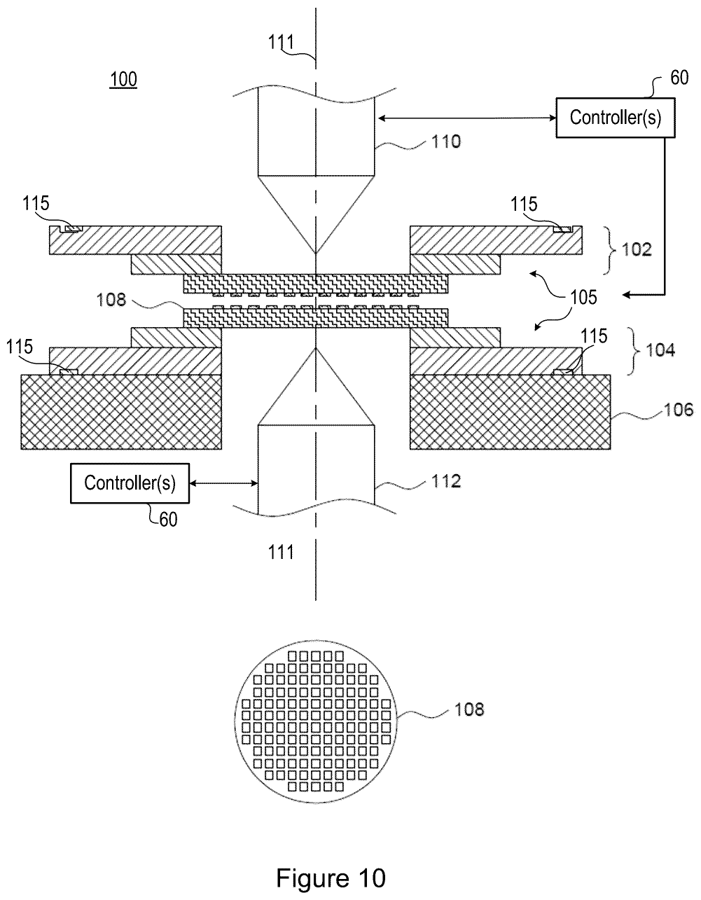

FIG. 10 is a high-level schematic illustration of the real-time alignment and inspection during material processing within the multi-layer and multi-functional system 100, according to some embodiments of the invention. FIG. 10 provides a schematic cross section of system 100 and a top view of semiconductor device 108 during fabrication. In operation, inspection head 112 is configured to scrutinize the alignment of the layers of holder 105 to detect any misalignments that could potentially impede the accuracy of semiconductor processing. Upon inspection, inspection head 112 identifies (e.g., by controller(s) 60) the degree of offset from the desired position for each misaligned layer of holder 105 (see non-limiting examples in FIGS. 8 and 9). The detected degrees of offset, as discerned by inspection head 112, form the basis for the subsequent realignment process. To rectify the error(s) in the predefined working parallelism or coplanarity, individual compensation mechanism(s) 115 are activated (e.g., by controller(s) 60) to shift and move the displaced layer(s) of holder 105 to their respective correct position(s) to attain the predefined working parallelism or coplanarity. This realignment is, in some embodiments, crucial to ensure that each layer is accurately positioned for precise and efficient processing of semiconductor device 108.

Furthermore, the individual compensation mechanism(s) 115 (e.g., actuators 115) implemented by controller(s) 60 in semiconductor processing system 100 may be designed for maintaining and adjusting the parallelism of processing materials along with various mechanical. For example, such mechanism(s) (e.g., actuators 115) may employ piezo-electric cylinders 115 (see, e.g., FIGS. 4A-8) that may be controlled to change shape under electrical voltage. Such piezo-electric cylinders 115, as a non-limiting example for actuators 115, may be integrally embedded within one or more of the layers of holder 105, positioning the respective layer(s) in the optimal position to effect the necessary adjustments for maintaining parallelism. Functionally, the disclosed alignment mechanism(s) may operate through a series of well-orchestrated steps, controlled by controller(s) 60. Initially, the alignment process may involve the acquisition of data from real time feedback regarding the parallelism between the processing materials. The data may be processed to highlight the deviations from the desired parallelism levels. Once acquired, the data may be analyzed, e.g., by controller(s) 60 of system 100 or associated therewith (e.g., through communication link(s), not shown), to ascertain the specific adjustments needed. Following the analysis, piezo-electric cylinders 115 may be activated by controller(s) 60 by application of corresponding voltages that causes the cylinders to expand or contract, thus adjusting their length in a controlled manner. The expansion or contraction of piezo-electric cylinders 115 may be adjusted by controller(s) 60 to precisely adjust the tilt or height of the holder layers, effectively correcting any misalignment and ensuring that the layers are kept parallel to each other. Disclosed mechanism(s) have the ability to perform these adjustments in real-time, to enable high-precision semiconductor processing tasks, avoiding even minor deviations to prevent significant impacts on the outcome. Additionally, disclosed mechanism(s) may be designed with a feedback loop (e.g., implemented by controller(s) 60), continually monitoring post-adjustment data to ensure that the desired parallelism is consistently maintained. In non-limiting examples, actuators 115 may be configured to have an accuracy enabling tilting upper frame 102A (XYθ stage) and lower frame 104A (XYθ stage), e.g., by 10 nm (possibly between 5-20 nm as minimal value or increment) in the Z direction, and less than 0.25 μrad (possibly between 0.1-0.5 μrad as minimal value or increment) in the angle (θ) of the respective stage.

The following provides a non-limiting example of the application of disclosed embodiments. Processing head 110 of system 100 may be equipped with a laser delivery system together with a scanhead or objective lens. The laser system may be selected from a group of a solid laser, a gas laser and a fiber laser, and an output wavelength of the laser is ultraviolet light of 200-400 nm, visible light of 400-700 nm or infrared light of 700-1000 nm. The laser system may be either incorporated with a specific wavelength or capable of generating pulses with a tuneable wavelength. In some embodiments, processing head 110 may be configured to allow using adjustable power output from 10 mW to 20 W, and a pulse duration of 1 ps to 500 ns. These parameters allow for precise localized energy application, ensuring that the energy applied to the semiconductor device is achieved with a thermal impact zone of less than 2 μm. This provides a precise control of the material modification and decomposition to the regions of interest in the process.

It is pointed out that in conventional platforms inspection units and processing units are typically separated, requiring additional steps and time to evaluate and optimize process outcomes. In contrast. Disclosed systems and methods introduce a novel design having the inspection unit(s) coaxially aligned with the processing unit(s) through specially designed hollow features (e.g., holder layers). Disclosed configurations allow the two system layers (processing unit(s) and inspection unit(s)) to be sandwiched together, enabling immediate feedback on the process results. This real-time evaluation capability permits operators to determine whether the process meets the desired outcomes and adjust parameters promptly, significantly improving efficiency and precision.

Furthermore, in addition to manual inspection and feedback by an operator, disclosed embodiments enable the integration of an automatic AI-based inspection system within the inspection head, e.g., in corresponding controller(s). By training the AI algorithm to recognize and evaluate expected process quality, the system can automatically optimize processing parameters in response to specific requirements, thereby minimizing manual intervention and enhancing accuracy.

As an application example of such embodiments, the laser transfer process for microLEDs (light emitting diodes) demonstrates the advantages of disclosed systems and methods. The laser transfer process involves several components: a processing head, such as a laser head equipped with a scan lens; a semiconductor materials and components layer, such as a donor wafer containing microLEDs; a semiconductor device substrate layer, such as a wafer substrate recipient; and an inspection head, such as a high-resolution camera.

During operation, the donor semiconductor materials and components wafer is aligned with the wafer substrate recipient through the inspection head, ensuring precision. Additionally, the multidirectional moving holder may have a tip-tilt mechanism (not shown, configured to compensate for misalignments as illustrated, e.g., in FIGS. 6 and 7), enabling the donor wafer to align parallel to the wafer substrate. These features together streamline the alignment and inspection process, allowing for precise laser transfer and process optimization in real time.

For example (sec, e.g., FIGS. 7A, 7B), when a donor wafer 108B containing microLEDs is loaded onto the second holder layer 102B and substrate board 108A is loaded onto the third holder layer 104B, a 5 μm misalignment in parallelism may occur due to differences in the coplanarity of the two wafers. This misalignment introduces a slight tilt angle, which can affect the precise alignment required for microLED transfer. To compensate for this, the tip-tilt mechanism applies different voltages to the respective piezoelectric cylinders 115. These voltages induce controlled adjustments to the holder layers, effectively reducing the tilt and bringing the donor wafer and substrate board into parallel alignment. This ensures high-precision transfer of the microLEDs while minimizing alignment errors.

The tip-tilt mechanism may be further configured to enable angular corrections with a resolution of up to 0.01 degrees, ensuring precise parallel alignment between the donor wafer and the recipient substrate. Misalignment tolerances in processes like microLED transfer, often limited to ±2 microns, are effectively addressed by this feature, minimizing errors and defects.

In various embodiments, disclosed systems and methods may be configured to support complex geometries for implementing disclosed processes. For example, in conventional alignment systems, wafer bowing or warping can lead to surface deviations of up to 50 microns across a 300 mm wafer, posing significant challenges. In contrast, disclosed tip-tilt mechanism may be configured to compensate for such variations, ensuring uniform contact and alignment across the entire wafer surface.

The integrated alignment mechanism, shown experimentally to reach an accuracy of ±1 μm, may utilize machine vision of inspection head 112 to align the donor and the recipient substrates (108B, 108A, respectively) dynamically. The inspection head may be configured to include one or more camera(s) of various resolutions to be incorporated to suit the needs of the size of the semiconductor device(s) that are required for the processing. In various embodiments, disclosed systems and methods may be configured to be capable of handling semiconductor devices of varying sizes, ranging from electronic components measured in millimeters to microLEDs as small as 10 μm×10 μm. This capability enables the precise transfer of ultra-fine pitch arrays with pitches smaller than 10 μm.

The modular design of system 100 supports multiple sizes and substrates for the processed semiconductor devices, such as glass substrates ranging from 2 inches to 4 inches or up to panel size PCBs, further enhancing scalability.

Advantageously, disclosed systems and methods may be configured to provide the following advantages compared to traditional platforms: (i) Precision and reliability: The processing head such as a laser, allows tightly controlled energy delivery and help eliminating collateral damage to adjacent structures, achieving defect rates below 0.1% for microLEDs. This precision ensures consistent performance, even for fragile or non-uniform materials; (ii) Scalability for mass production: With the disclosed modular configuration, the system platform can seamlessly scale to handle larger substrate sizes or higher throughput demand; (iii) Material versatility: The system platform supports a wide range of donor and recipient substrates, including glass, sapphire, and flexible polymers, with thicknesses from 50 μm to 1 mm; and (iv) Improved integration: The system's ability to transfer microLED arrays with pitches as fine as 5 μm aligns with the stringent requirements of next-generation displays.

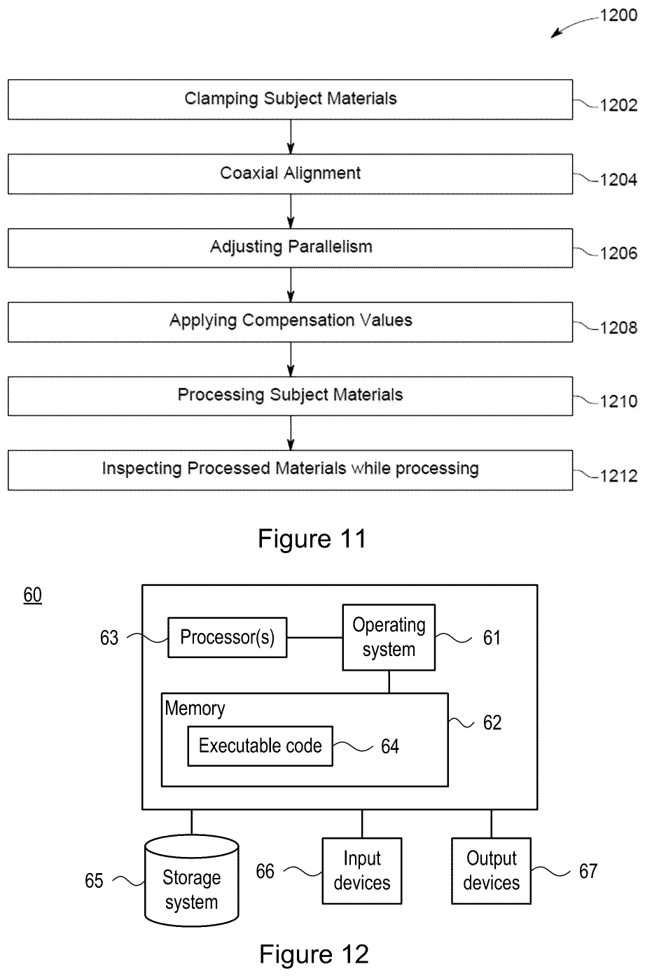

FIG. 11 is a high-level flowchart illustrating a method 1200 of semiconductor processing using a multi-layer platform, according to some embodiments of the invention. The method stages may be carried out with respect to system 100 described above, as a non-limiting example for the multi-layer platform, which may optionally be configured to implement method 1200. Method 1200 may be at least partially implemented by at least one computer processor, e.g., in controller(s) 60 illustrated schematically in FIG. 12. Certain embodiments comprise computer program products comprising a computer readable storage medium having computer readable program embodied therewith and configured to carry out the relevant stages of method 1200. Method 1200 may comprise the following stages, irrespective of their order.

Method 1200 may comprise, initially, securely clamped one or more subject materials onto a plurality of device (holder) layers within the platform (stage 1202). The clamping mechanism ensures that the materials are held firmly in place, preventing any unwanted movement that could interfere with the accuracy of subsequent processing and inspection tasks. Method 1200 may further comprise, following the clamping, carrying out an alignment process to ensure that the plurality of mechanical layers within the platform are coaxially aligned (stage 1204). This alignment ensures that the processing and inspection heads are correctly positioned relative to the device (holder) layers and the subject materials. The coaxial alignment helps in maintaining the correct positional relationship among the layers which is vital for the accuracy of the processing tasks.

Method 1200 may further comprise, if any error in parallelism is identified in any of layers, applying required adjustments to the parallelism of the plurality of device (holder) layers based on an individual compensation mechanism(s) disclosed herein (stage 1206). Compensation mechanism(s) may be configured to allow for precise adjustments to the alignment of the device (holder) layers and processing head to ensure that they are co-planar and correctly positioned for any further processing tasks.

Method 1200 may further comprise applying distinct values or modes of compensation to each device (holder) layer to optimize the processing alignment (stage 1208). This step ensures that each layer is perfectly aligned and prepared for any subsequent processing tasks. By applying distinct compensation values, the platform is fine-tuned to ensure the highest level of precision and accuracy in the semiconductor processing workflow.

Method 1200 may further comprise, once the layers are accurately aligned, commencing the processing phase (stage 1210). The processing head may be employed to carry out the necessary processing tasks on the subject materials. The type of processing could range from, but not limited to, laser processing, etching, deposition, among others, depending on the specific requirements of the semiconductor manufacturing process.

Method 1200 may further comprise, during the processing, simultaneous inspection of the processed materials by the inspection head (stage 1212) to ensure that the processing tasks are being carried out accurately and to verify the quality and integrity of the processed materials. Any discrepancies or misalignment identified during the inspection could be rectified in the subsequent steps. If additional adjustments are required during the process, stages 1204, 1206 and 1208 may iterated until the process is finished.

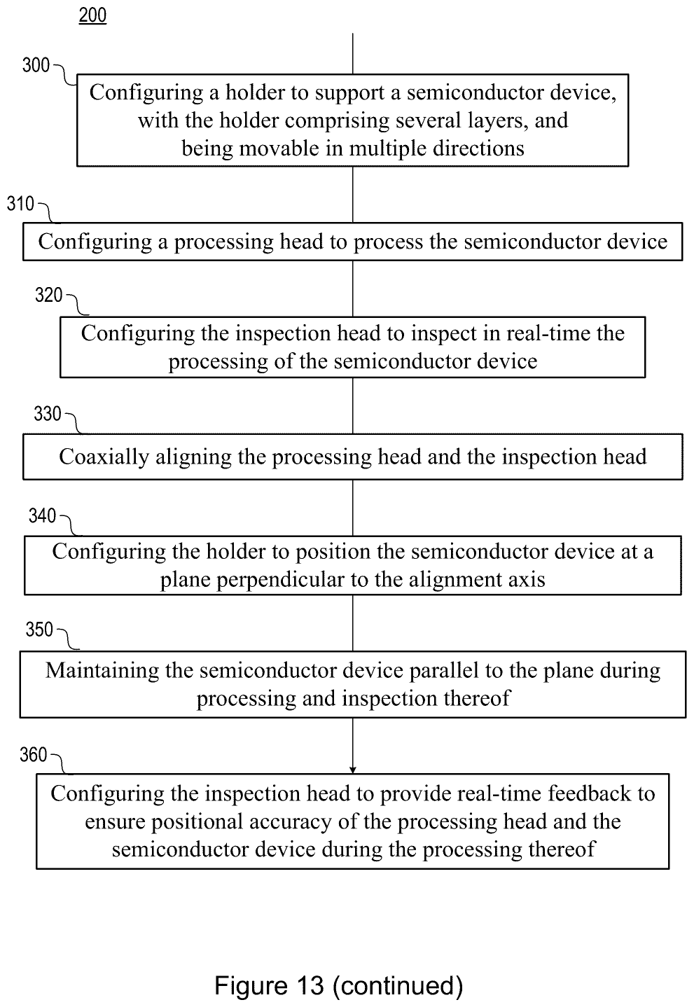

FIG. 13 is a high-level flowchart illustrating a method 200 of concurrent processing and inspection of semiconductor devices (stage 205), according to some embodiments of the invention. The method stages may be carried out with respect to system 100 described above, as a non-limiting example for the multi-layer platform, which may optionally be configured to implement method 200. Method 200 may be at least partially implemented by at least one computer processor, e.g., in controller(s) 60 illustrated schematically in FIG. 12. Certain embodiments comprise computer program products comprising a computer readable storage medium having computer readable program embodied therewith and configured to carry out the relevant stages of method 200. Stages of methods 200 and 1200 may be implemented in any operable combination. Method 200 may comprise the following stages, irrespective of their order.

Method 200 may comprise clamping the semiconductor device onto the holder (stage 210), coaxially aligning the plurality of layers of the holder (stage 220), and using at least one hollow frame or layer of the holder to align the layers of the holder through independent or synchronized movements (stage 230).

Method 200 may comprise processing the semiconductor device using the processing head (stage 240) and inspecting the processed semiconductor device using the inspection head (stage 250).

In some embodiments, method 200 further comprises adjusting a parallelism of the holder layers based on an individual compensation mechanism (stage 232) and applying distinct values or modes of compensation to each holder layer for optimized processing alignment (stage 234).

In some embodiments, using of hollow frame(s) or layer(s) 230 comprises facilitating real-time alignment during processing (stage 252) and obtaining real-time feedback of position accuracy, thereby mitigating offsets between the inspection and processing axes (stage 254).

In some embodiments, method 200 may comprise configuring a holder to support a semiconductor device (stage 300), wherein the holder comprises a plurality of layers, and is movable in multiple directions, configuring a processing head to process the semiconductor device (stage 310), configuring the inspection head to inspect in real-time the processing of the semiconductor device (stage 320), coaxially aligning the processing head and the inspection head (stage 330), configuring the holder to position the semiconductor device at a plane perpendicular to the alignment axis (stage 340), maintaining the semiconductor device parallel to the plane during processing and inspection thereof (stage 350), and configuring the inspection head to provide real-time feedback to ensure positional accuracy of the processing head and the semiconductor device during the processing thereof (stage 360).

In some embodiments, method 200 may further comprise processing the semiconductor device using the processing head (stage 352) and inspecting the processed semiconductor device using the inspection head (stage 354).

In some embodiments, method 200 may further comprise adjusting a parallelism of the holder layers based on individual compensation mechanism(s) (stage 232) and applying distinct values or modes of compensation to each holder layer for optimized processing alignment (stage 234).

In some embodiments, method 200 may further comprise using at least one hollow frame of the holder to align the layers of the holder through independent or synchronized movements (stage 230).

In some embodiments, using of the at least one hollow frame 230 may comprise facilitating real-time alignment during processing (stage 252) and obtaining real-time feedback of position accuracy, thereby mitigating offsets between the inspection and processing axes (stage 254).

Various embodiments comprise computer program products comprising a non-transitory computer readable storage medium having computer readable program embodied therewith, the computer readable program comprising: computer readable program configured to control concurrent processing and inspection of semiconductor devices by coaxially aligning a processing head configured to process a semiconductor device and an inspection head configured to inspect in real-time the processing of the semiconductor device, and computer readable program configured to control a holder, configured to support the semiconductor device, comprising a plurality of layers, and being movable in multiple directions-to position the semiconductor device at a plane perpendicular to the alignment axis, and maintain the semiconductor device parallel to the plane during processing and inspection thereof.

In some embodiments, the computer readable program further comprises computer readable program configured to control the processing of the semiconductor device using the processing head, computer readable program configured to control the inspecting of the processed semiconductor device using the inspection head, and computer readable program configured to facilitate real-time alignment during the processing, computer readable program configured to obtain real-time feedback of position accuracy, thereby mitigating offsets between the inspection and processing axes.

In some embodiments, the computer readable program further comprises computer readable program configured to adjust a parallelism of the holder layers based on an individual compensation mechanism, and computer readable program configured to apply distinct values or modes of compensation to each holder layer for optimized processing alignment.

FIG. 12 is a high-level block diagram of exemplary controllers 60, which may be used with embodiments of the present invention. Controller(s) 60 may include one or more controller or processor 63 that may be or include, for example, one or more central processing unit processor(s) (CPU), one or more Graphics Processing Unit(s) (GPU or general-purpose GPU-GPGPU), a field-programmable gate array (FPGA), an application-specific integrated circuit (ASIC), a digital signal processor (DSP), a microprocessor, a chip, a microchip, an integrated circuit (IC), or any other suitable multi-purpose or specific processor, controller or computational device, an operating system 61, a memory 62, a storage 65, input devices 66 and output devices 67.

Operating system 61 may be or may include any code segment designed and/or configured to perform tasks involving coordination, scheduling, arbitration, supervising, controlling, or otherwise managing operation of controller(s) 60, for example, scheduling execution of programs. Memory 62 may be or may include, for example, a Random-Access Memory (RAM), a read only memory (ROM), a Dynamic RAM (DRAM), a Synchronous DRAM (SD-RAM), a double data rate (DDR) memory chip, a Flash memory, a volatile memory, a non-volatile memory, a cache memory, a buffer, a short-term memory unit, a long-term memory unit, or other suitable memory units or storage units. Memory 62 may be or may include a plurality of possibly different memory units. Memory 62 may store for example, instructions to carry out a method (e.g., code 64), and/or data such as user responses, interruptions, etc.

Executable code 64 may be any executable code, e.g., an application, a program, a process, task or script. Executable code 64 may be executed by controller 63 possibly under control of operating system 61. For example, executable code 64 may when executed cause the production or compilation of computer code, or application execution such as VR execution or inference, according to embodiments of the present invention. Executable code 64 may be code produced by methods described herein. For the various modules and functions described herein, one or more computing devices and/or components of controller(s) 60 may be used. Devices that include components similar or different to those included in controller(s) 60 may be used and may be connected to a network and used as a system. One or more processor(s) 63 may be configured to carry out embodiments of the present invention by for example executing software or code.

Storage 65 may be or may include, for example, a hard disk drive, a floppy disk drive, a Compact Disk (CD) drive, a CD-Recordable (CD-R) drive, a universal serial bus (USB) device or other suitable removable and/or fixed storage unit. Data such as instructions, code, VR model data, parameters, etc. may be stored in a storage 65 and may be loaded from storage 65 into a memory 62 where it may be processed by controller 63. In some embodiments, some of the components shown in FIG. 12 may be omitted.

Input devices 66 may be or may include for example a mouse, a keyboard, a touch screen or pad or any suitable input device. It will be recognized that any suitable number of input devices may be operatively connected to controller(s) 60 as shown by block 66. Output devices 67 may include one or more displays, speakers and/or any other suitable output devices. It will be recognized that any suitable number of output devices may be operatively connected to controller(s) 60 as shown by block 67. Any applicable input/output (I/O) devices may be connected to controller(s) 60, for example, a wired or wireless network interface card (NIC), a modem, printer or facsimile machine, a universal serial bus (USB) device or external hard drive may be included in input devices 66 and/or output devices 67.

Embodiments of the invention may include one or more article(s) (e.g., memory 62 or storage 65) such as a computer or processor non-transitory readable medium, or a computer or processor non-transitory storage medium, such as for example a memory as disclosed herein, a disk drive, or a USB flash memory, encoding, including or storing instructions, e.g., computer-executable instructions, which, when executed by a processor or controller, carry out methods disclosed herein.

Advantageously, disclosed systems 100 and methods 200, 1200 provide at least some of the following improvements compared to the prior art.

Enhanced precision: The design of the platform, with its coaxial alignment and individual compensation mechanisms, significantly enhances the precision of semiconductor processing. The provision for real-time alignment and feedback further augments the accuracy in processing and inspection tasks.

Real-time inspection and alignment: The hollow coaxial feature (e.g., the hollow adjustable layer(s) arrangement) enables real-time alignment and inspection, and was previously challenging to achieve. The real-time capability ensures that any misalignments are promptly detected and corrected, thereby reducing the likelihood of processing errors.

Increased efficiency: By allowing for real-time adjustments and inspections, the platform minimizes the time traditionally needed to halt and adjust the process for alignment issues. This leads to increased efficiency and throughput in the semiconductor manufacturing process.

Independent layer adjustment: The ability to independently adjust the parallelism of the holder layers enables more precise control over the processing environment. This feature is, in some embodiments, crucial for handling semiconductor materials that may have different requirements for processing.

Optimized processing alignment: The platform allows for the application of distinct values or modes of compensation to each holder layer, ensuring optimized processing alignment. This feature is, in some embodiments, instrumental in meeting the ultra-precise requirements of semiconductor processing.

Improved coplanarity: The individual compensation mechanism(s) enable better coplanarity of the holder layers, overcoming the limitations posed by traditional hardware in achieving micron-level precision.

Reduced system errors: By eliminating the offset between the inspection and processing axes, the platform significantly reduces system errors, thereby improving the overall reliability and accuracy of the semiconductor processing.

Modular and scalable design: The design of the platform is such that it can be integrated as a critical feature of semiconductor processing equipment or used independently as a testing platform. This modular and scalable design makes it a flexible solution for various process evaluations and semiconductor manufacturing needs.

Various modifications to these embodiments are apparent to those skilled in the art from the description and the accompanying drawings. The principles associated with the various embodiments described herein may be applied to other embodiments. Therefore, the description is not intended to be limited to the embodiments shown along with the accompanying drawings but is to be providing broadest scope, consistent with the principles and the novel and inventive features disclosed or suggested herein. Accordingly, the invention is anticipated to hold on to all other such alternatives, modifications, and variations that fall within the scope of the present invention and the appended claims.

Elements from FIGS. 1-13 may be combined in any operable combination, and the illustration of certain elements in certain figures and not in others merely serves an explanatory purpose and is non-limiting.

Aspects of the present invention are described above with reference to flowchart illustrations and/or portion diagrams of methods, apparatus (systems) and computer program products according to embodiments of the invention. It will be understood that each portion of the flowchart illustrations and/or portion diagrams, and combinations of portions in the flowchart illustrations and/or portion diagrams, can be implemented by computer program instructions. These computer program instructions may be provided to a processor of a general-purpose computer, special purpose computer, or other programmable data processing apparatus to produce a machine, such that the instructions, which execute via the processor of the computer or other programmable data processing apparatus, create means for implementing the functions/acts specified in the flowchart and/or portion diagram or portions thereof.

These computer program instructions may also be stored in a computer readable medium that can direct a computer, other programmable data processing apparatus, or other devices to function in a particular manner, such that the instructions stored in the computer readable medium produce an article of manufacture including instructions which implement the function/act specified in the flowchart and/or portion diagram or portions thereof.

The computer program instructions may also be loaded onto a computer, other programmable data processing apparatus, or other devices to cause a series of operational steps to be performed on the computer, other programmable apparatus or other devices to produce a computer implemented process such that the instructions which execute on the computer or other programmable apparatus provide processes for implementing the functions/acts specified in the flowchart and/or portion diagram or portions thereof.

The aforementioned flowchart and diagrams illustrate the architecture, functionality, and operation of possible implementations of systems, methods and computer program products according to various embodiments of the present invention. In this regard, each portion in the flowchart or portion diagrams may represent a module, segment, or portion of code, which comprises one or more executable instructions for implementing the specified logical function(s). It should also be noted that, in some alternative implementations, the functions noted in the portion may occur out of the order noted in the figures. For example, two portions shown in succession may, in fact, be executed substantially concurrently, or the portions may sometimes be executed in the reverse order, depending upon the functionality involved. It will also be noted that each portion of the portion diagrams and/or flowchart illustration, and combinations of portions in the portion diagrams and/or flowchart illustration, can be implemented by special purpose hardware-based systems that perform the specified functions or acts, or combinations of special purpose hardware and computer instructions.

In the above description, an embodiment is an example or implementation of the invention. The various appearances of “one embodiment”, “an embodiment”, “certain embodiments” or “some embodiments” do not necessarily all refer to the same embodiments. Although various features of the invention may be described in the context of a single embodiment, the features may also be provided separately or in any suitable combination. Conversely, although the invention may be described herein in the context of separate embodiments for clarity, the invention may also be implemented in a single embodiment. Certain embodiments of the invention may include features from different embodiments disclosed above, and certain embodiments may incorporate elements from other embodiments disclosed above. The disclosure of elements of the invention in the context of a specific embodiment is not to be taken as limiting their use in the specific embodiment alone. Furthermore, it is to be understood that the invention can be carried out or practiced in various ways and that the invention can be implemented in certain embodiments other than the ones outlined in the description above.

The invention is not limited to those diagrams or to the corresponding descriptions. For example, flow need not move through each illustrated box or state, or in exactly the same order as illustrated and described. Meanings of technical and scientific terms used herein are to be commonly understood as by one of ordinary skill in the art to which the invention belongs, unless otherwise defined. While the invention has been described with respect to a limited number of embodiments, these should not be construed as limitations on the scope of the invention, but rather as exemplifications of some of the preferred embodiments. Other possible variations, modifications, and applications are also within the scope of the invention. Accordingly, the scope of the invention should not be limited by what has thus far been described, but by the appended claims and their legal equivalents.

What is claimed is:

1. A system for concurrent processing and inspection of semiconductor devices, the system comprising:
a holder configured to support a semiconductor device and semiconductor materials to be deposited onto the semiconductor device during processing thereof, wherein the holder comprises a plurality of layers, and is movable in multiple directions,
a processing head configured to process the semiconductor device, and
an inspection head configured to inspect in real-time the processing of the semiconductor device, wherein:
the processing head and the inspection head are coaxially aligned and the holder is configured to position the semiconductor device and the semiconductor materials at a plane perpendicular to the alignment axis, and maintain the semiconductor device and the semiconductor materials parallel to the plane during processing and inspection thereof, and
the inspection head is configured to provide real-time feedback to ensure positional accuracy of the processing head, the semiconductor device and the semiconductor materials during the processing thereof.

2. The system of claim 1, wherein the holder comprises at least one hollow frame configured to support the semiconductor device and the semiconductor materials, and allow optical access of the processing head and the inspection head to the device.

3. The system of claim 1, wherein the at least one hollow frame is further configured to enable real-time alignment and feedback of position accuracy during processing, eliminating possible lateral offset between an inspection axis and a processing axis.

4. The system of claim 1, wherein the holder comprises a top layer comprising an upper clamping surface and a bottom layer comprising a lower clamping surface configured to support the semiconductor device and the semiconductor materials.

5. The system of claim 1, further comprising at least one controller configured to control the holder, the processing head and the inspection head to maintain a coplanarity of the holder layers, the semiconductor device and the semiconductor materials, and their perpendicular relation to the alignment axis of the processing head and the inspection head during processing and inspection.

6. The system of claim 5, wherein the at least one controller is configured to implement a compensation mechanism for adjusting orientations of the plurality of holder layers individually.

7. The system of claim 1, wherein the processing head comprises at least one of: a laser head, a scan lens, an objective lens, mechanical pick and place working parts, needles, sensors, detectors, and cameras.

8. The system of claim 1, wherein the inspection head comprises a sensing system with at least one of: lighting, cameras, thermal sensors, and detectors.

9. A method of concurrent processing and inspection of semiconductor devices using the system of claim 1, the method comprising:
clamping the semiconductor device onto the holder;
coaxially aligning the plurality of layers of the holder; and
using at least one hollow frame of the holder to align the layers of the holder through independent or synchronized movements.

10. The method of claim 9, further comprising processing the semiconductor device using the processing head; and inspecting the processed semiconductor device using the inspection head.

11. The method of claim 9, further comprising adjusting a parallelism of the holder layers based on an individual compensation mechanism; and applying distinct values or modes of compensation to each holder layer for optimized processing alignment.

12. The method of claim 9, wherein the using of the at least one hollow frame comprises facilitating real-time alignment during processing; and obtaining real-time feedback of position accuracy, thereby mitigating offsets between the inspection and processing axes.

13. A method of concurrent processing and inspection of semiconductor devices, the method comprising:
configuring a holder to support a semiconductor device and semiconductor materials to be deposited onto the semiconductor device during processing thereof, wherein the holder comprises a plurality of layers, and is movable in multiple directions,
configuring a processing head to process the semiconductor device using the semiconductor materials,
configuring the inspection head to inspect in real-time the processing of the semiconductor device,
coaxially aligning the processing head and the inspection head,
configuring the holder to position the semiconductor device and the semiconductor materials at a plane perpendicular to the alignment axis,
maintaining the semiconductor device and the semiconductor materials parallel to the plane during processing and inspection thereof, and
configuring the inspection head to provide real-time feedback to ensure positional accuracy of the processing head, the semiconductor device and the semiconductor materials during the processing thereof.

14. The method of claim 13, further comprising processing the semiconductor device using the processing head; and inspecting the processed semiconductor device using the inspection head.

15. The method of claim 13, further comprising adjusting a parallelism of the holder layers based on an individual compensation mechanism; and applying distinct values or modes of compensation to each holder layer for optimized processing alignment.

16. The method of claim 13, further comprising using at least one hollow frame of the holder to align the layers of the holder through independent or synchronized movements.

17. The method of claim 16, wherein the using of the at least one hollow frame comprises facilitating real-time alignment during processing; and obtaining real-time feedback of position accuracy, thereby mitigating offsets between the inspection and processing axes.

18. A computer program product comprising a non-transitory computer readable storage medium having computer readable program embodied therewith, the computer readable program comprising:
computer readable program configured to control concurrent processing and inspection of semiconductor devices by coaxially aligning a processing head configured to process a semiconductor device and an inspection head configured to inspect in real-time the processing of the semiconductor device, and
computer readable program configured to control a holder, configured to support the semiconductor device and semiconductor materials to be deposited onto the semiconductor device during processing thereof, the holder comprising a plurality of layers, and being movable in multiple directions-to position the semiconductor device at a plane perpendicular to the alignment axis, and maintain the semiconductor device and the semiconductor materials parallel to the plane during processing and inspection thereof.

19. The computer program product of claim 18, wherein the computer readable program further comprises:
computer readable program configured to control the processing of the semiconductor device using the processing head,
computer readable program configured to control the inspecting of the processed semiconductor device using the inspection head, and
computer readable program configured to facilitate real-time alignment during the processing, and
computer readable program configured to obtain real-time feedback of position accuracy, thereby mitigating offsets between the inspection and processing axes.

20. The computer program product of claim 18, wherein the computer readable program further comprises:
computer readable program configured to adjust a parallelism of the holder layers based on an individual compensation mechanism, and
computer readable program configured to apply distinct values or modes of compensation to each holder layer for optimized processing alignment.
